(19) United States
(12) Patent Application Publication
(10) Pub. No.: US 2026/0043752 A1
(43) Pub. Date: Feb. 12, 2026

(54) MASK INSPECTION APPARATUS, VACUUM SEAL COMPONENT, AND METHOD FOR ADJUSTING A MASK INSPECTION APPARATUS

(71) Applicant: Carl Zeiss SMT GmbH, Oberkochen (DE)

(72) Inventors: Lutz Brekerbohm, Hardegsen (DE); Robert Roeder, Jena (DE); Tobias Hoerold, Ilmenau (DE)

(21) Appl. No.: 19/290,862

(22) Filed: Aug. 5, 2025

(30) Foreign Application Priority Data
Aug. 9, 2024 (DE) 102024122887.3

(51) Int. Cl. G01N 21/956; G03F 7/00

(52) U.S. Cl. CPC G01N 21/956; G03F 7/7065; G03F 7/706845; G03F 7/706851; G01N 2021/95676; G01N 2201/0227

(57) ABSTRACT

A mask inspection apparatus, a vacuum seal component and a method for adjusting a mask inspection apparatus. A mask inspection apparatus comprises a vacuum housing, an EUV camera mounted on the vacuum housing, and a projection lens, arranged in a vacuum chamber of the vacuum housing, for imaging at least one section of an EUV mask onto an image sensor of the EUV camera, wherein a vacuum seal component having a flexible wall portion is arranged between the vacuum housing and the EUV camera or a camera holder of this EUV camera, and wherein this flexible wall portion is arranged radially outside of a central axis of the EUV camera or of the camera holder.

### CROSS-REFERENCE TO RELATED APPLICATION

This application claims priority of German Application No. 10 2024 122 887.3, filed on Aug. 9, 2024. The entire content of this application is herein incorporated by reference.

### TECHNICAL FIELD

The invention relates to a mask inspection apparatus, to a vacuum seal component and to a method for adjusting a mask inspection apparatus.

### BACKGROUND

Microlithography is used for producing microstructured components, such as integrated circuits or LCDs. The microlithography process is performed in what is known as a projection exposure apparatus, which comprises an illumination device and a projection lens. The image of a mask (=reticle) illuminated by use of the illumination device is in this case projected by use of the projection lens onto a substrate (e.g. a silicon wafer) coated with a light-sensitive layer (photoresist) and arranged in the image plane of the projection lens, in order to transfer the mask structure to the light-sensitive coating on the substrate.

Unwanted defects on the mask have a particularly disadvantageous effect in the lithography process as these defects may be reproduced in each exposure step and hence, in a worst-case scenario, there is the risk of the entire output of semiconductor components being unusable. Therefore, it is very important to check the mask has a sufficient imaging capability prior to the use thereof within the scope of mass production. There is thus a need to test the mask quickly and easily, if possible under conditions similar to those that are actually present in the projection exposure apparatus. To this end, the use of mask inspection apparatuses is known, said mask inspection apparatuses comprising, within a vacuum housing, an illumination system and a projection lens, with the illuminated region of the mask being imaged onto an image sensor of an EUV camera by use of the projection lens.

Here, the mask inspection apparatus should be adjusted in such a way as to result in entirely satisfactory imaging of the EUV mask onto the image sensor. A possible approach for this involves the implementation of an EUV camera, the position of which relative to the imaging beam path of the projection lens or to a vacuum housing containing the latter is discretely or continuously adjustable.

However, a problem that arises in practice is that the installation space available for providing the mentioned position manipulation or actuatability is relatively greatly restricted. Here, it is in particular also desirable to not significantly increase the distance of the camera from the vacuum housing by use of the adjustment mechanism required for the position manipulation, in order to avoid defocusing when generating the camera image.

The realization of the adjustability of a mask inspection apparatus taking account of existing installation space restrictions therefore constitutes a demanding challenge against the background of the vacuum conditions that are to be ensured (i.e. the maintenance of pressure differences present between the inner region and the outer region of the vacuum chamber).

### SUMMARY

Against the above background, it is an aspect of the present invention to provide a mask inspection apparatus, a vacuum seal component, and a method for adjusting a mask inspection apparatus which enable an adjustment while at least partly avoiding the problems described above.

This aspect is achieved according to the features of the independent claims.

According to one aspect, the invention relates to a mask inspection apparatus comprising a vacuum housing, an EUV camera mounted on the vacuum housing, and a projection lens, arranged in a vacuum chamber of the vacuum housing, for imaging at least one section of an EUV mask onto an image sensor of the EUV camera,
wherein a vacuum seal component having a flexible wall portion is arranged between the vacuum housing and the EUV camera or a camera holder of this EUV camera, and
wherein this flexible wall portion is arranged radially outside of a central axis of the EUV camera or of the camera holder.

In embodiments of the invention, the angle between a plane defined by the wall portion and the central axis has a value in the range from 0° to 180°, in particular in the range from 45° to 135°, more particularly in the range from 80° to 100°, more particularly in the range from 85° to 95°.

According to one embodiment, a plane defined by the wall portion runs orthogonally with respect to the central axis. In a preferred embodiment, the angle between a plane defined by the wall portion and the central axis is thus 90°.

The invention is in particular based on the concept of arranging, in a mask inspection apparatus for enabling an adjustment of the EUV camera relative to the imaging beam path of the projection lens, a vacuum seal component between the vacuum housing and the EUV camera or camera holder in such a way that a flexible wall portion of the vacuum seal component according to the invention is arranged substantially perpendicularly with respect to said central axis of the EUV camera or camera holder. As a result, this geometry of the construction according to the invention achieves a significant saving on installation space in an axial direction in relation to said central axis, and at the same time an actuatability or position manipulation of the EUV camera that is required for the adjustment is enabled by way of the flexible adaptation of the vacuum seal component while ensuring the vacuum conditions. In this case, as described below, the invention makes it possible, in particular during an adjustment, to carry out a tilting of the EUV camera relative to the vacuum housing about at least one axis which is orthogonal to the central axis, in particular about two axes which are orthogonal to one another and to the central axis.

In this case, with the geometric arrangement according to the invention, a comparatively increased installation space is purposefully accepted in a lateral direction (i.e. in a plane perpendicular to the central axis) in order to, in return, obtain the above saving on installation space in the axial direction. Here, the invention also makes use of the fact that said installation space in the lateral direction is typically more easily tolerable.

Overall, the invention provides the possibility of realizing adjustment travels of the EUV camera that are required for an adjustment and in doing so of largely maintaining the image distance between the camera and the optical unit of the projection lens with a corresponding saving on installation space, that is to say of not significantly increasing the required installation space as a result of the adjustment mechanism used for the position manipulation.

The formulation “plane defined by the wall portion” should be understood here as meaning including, in the case of an annular-disc-like or perforated-disc-like geometry of the wall portion, a plane in which the corresponding disc extends or which is spanned by this disc. In the case of a fold structure, which may be present in embodiments of the invention as described below, of the wall portion, the plane in question is understood to mean the plane which spans a wall portion formed analogously without this fold structure or a corresponding (annular or perforated) disc.

The central axis of the EUV camera may be (but does not necessarily have to be) in a direction perpendicular to a surface of an image sensor of the EUV camera, in particular to a surface of the image sensor for detecting EUV light. The central axis of the EUV camera may preferably be perpendicular to all the surfaces of the EUV camera which are designed to detect EUV light. The central axis may, for example, intersect a center of gravity of the EUV camera, the EUV camera being able to have any desired geometry, for example cylindrical or cuboid.

In other embodiments, the central axis of the EUV camera may also be in a direction which is not perpendicular to a surface of an image sensor of the EUV camera. For example, suppose the incoming light ray propagates along the z direction (as defined e.g. in FIG. 1 or FIGS. 3A-3B), and a mirror in the camera is used to reflect the light at 90 degrees, then the surface of the image sensor can extend in the z direction, so the axis perpendicular to the surface of the image sensor extends in the x-y plane, which is parallel to the flexible wall portion.

According to one embodiment, the wall portion has a fold structure running around the central axis. The wall portion may be designed as bellows or folding bellows.

According to one embodiment, the wall portion is produced from a metallic material, in particular stainless steel.

According to one embodiment, the wall portion is produced from a vacuum-suitable flexible material, in particular a vacuum-suitable rubber material.

According to one embodiment, the mask inspection apparatus comprises an adjustment mechanism by way of which the position of the EUV camera is adjustable relative to the vacuum housing.

According to one embodiment, this adjustability comprises a translational displacement in the direction of the central axis, in particular with an adjustment travel at least in the range from 0.1 mm to 2 mm.

According to one embodiment, this adjustability comprises a tilting about at least one axis which is orthogonal to the central axis, in particular about two axes which are orthogonal to one another and to the central axis.

According to one embodiment, this tilting is realizable at least up to an angle of 5°, in particular up to an angle of 10° with respect to the central axis.

The design according to the invention of a vacuum seal component is also advantageous independently of the specific use in the mask inspection apparatus according to the invention. According to a further aspect, the invention therefore also relates to a vacuum seal component which is independent of this use and has a flexible wall portion which extends around a central axis of the vacuum seal component, there being fastened to the flexible wall portion radially at the outside in relation to the central axis a first flange element for fastening to a first component and radially at the inside in relation to the central axis a second flange element for fastening to a second component.

In embodiments of the vacuum seal component, the angle between a plane defined by the wall portion and the central axis has a value in the range from 0° to 180°, in particular in the range from 45° to 135°, more particularly in the range from 80° to 100°, more particularly in the range from 85° to 95°.

According to a preferred embodiment, a plane defined by the wall portion runs orthogonally with respect to the central axis. In a preferred embodiment, the angle between a plane defined by the wall portion and the central axis is thus 90°.

According to one embodiment, the wall portion has a fold structure running around the central axis.

According to one embodiment, the wall portion is produced from a metallic material, in particular stainless steel.

According to one embodiment, the wall portion is produced from a vacuum-suitable rubber material.

The invention furthermore also relates to a method for adjusting a mask inspection apparatus, wherein the mask inspection apparatus comprises a vacuum housing, an EUV camera mounted on the vacuum housing, and a projection lens, arranged in a vacuum chamber of the vacuum housing, for imaging at least one section of an EUV mask onto an image sensor of the EUV camera,
wherein the mask inspection apparatus is designed according to the features described above; and
wherein the position of the EUV camera is adjusted relative to the vacuum housing, in order to adjust the EUV camera relative to the imaging beam path of the projection lens.

Further refinements of the invention can be gathered from the description and the dependent claims.

Below, the invention is explained in more detail on the basis of preferred exemplary embodiments and with reference to the attached figures.

### BRIEF DESCRIPTION OF THE DRAWINGS

In the figures:

FIG. 1 shows a schematic illustration for explaining an exemplary embodiment of the invention, which in particular shows a vacuum seal component having a flexible wall portion;

FIG. 2 shows a schematic illustration of a part of the arrangement from FIG. 1 in plan view;

FIG. 3A shows a schematic illustration for explaining the mechanical attachment of the arrangement from FIG. 1 to an EUV camera with realization of an adjustment mechanism;

FIG. 3B shows a schematic illustration for explaining the mechanical attachment of the arrangement from FIG. 1 to an EUV camera according to a further embodiment; and

FIGS. 4-6 show schematic illustrations for explaining a possible basic construction of a mask inspection apparatus.

### DETAILED DESCRIPTION

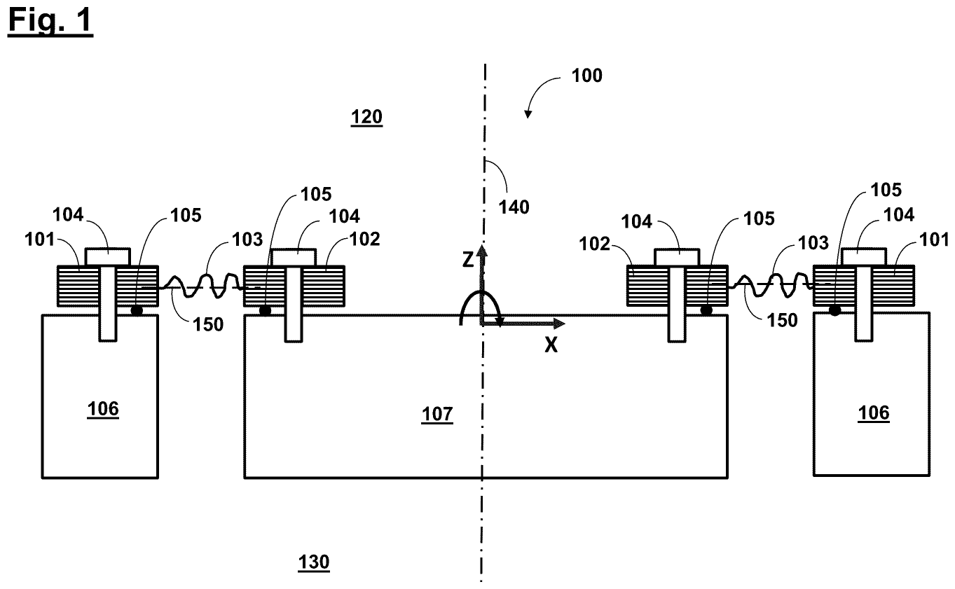

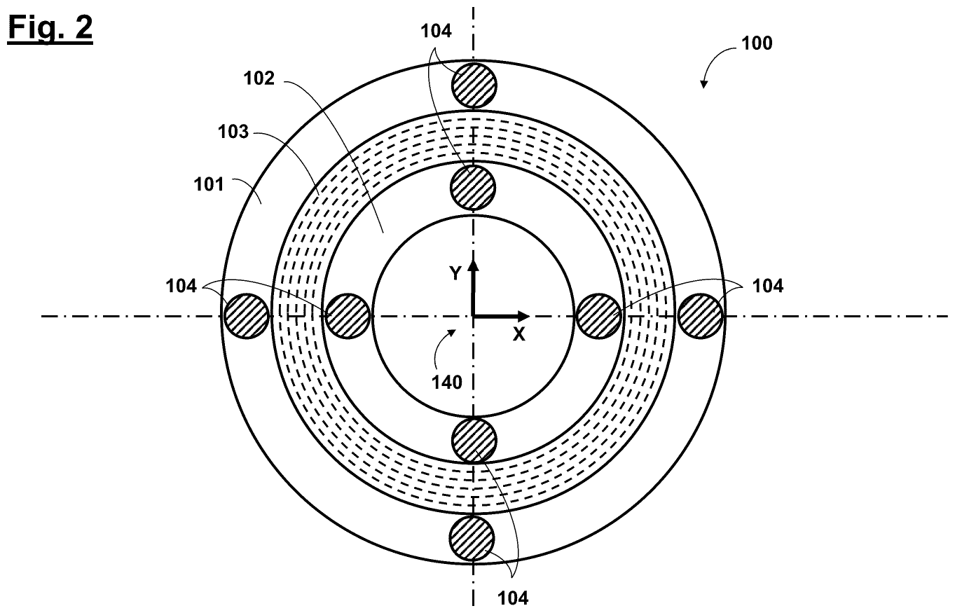

Below, an exemplary embodiment of the invention is first explained with reference to the schematic illustrations of FIG. 1 and FIG. 2, FIG. 1 showing a sectional view and FIG. 2 a plan view of a part of the arrangement from FIG. 1.

FIG. 1 and FIG. 2 in particular illustrate a vacuum seal component which has a flexible wall portion 103 which extends around a central axis, denoted by “140”, of the vacuum seal component. This central axis 140 runs along the z-axis in the coordinate system that is also depicted. There is fastened to the flexible wall portion 103 radially at the outside in relation to the central axis 140 a first flange element 101 and radially at the inside in relation to the central axis 140 a second flange element 102. The flange elements 101, 102 in turn serve for fastening (realized in this case for example by way of fastening screws 104) to a first component and a second component, respectively. Seals that are present are denoted by “105”.

The inner radius of the flexible wall portion 103 is larger than the distance between the central axis 140 and the outermost edge of the EUV camera or the camera holder, respectively.

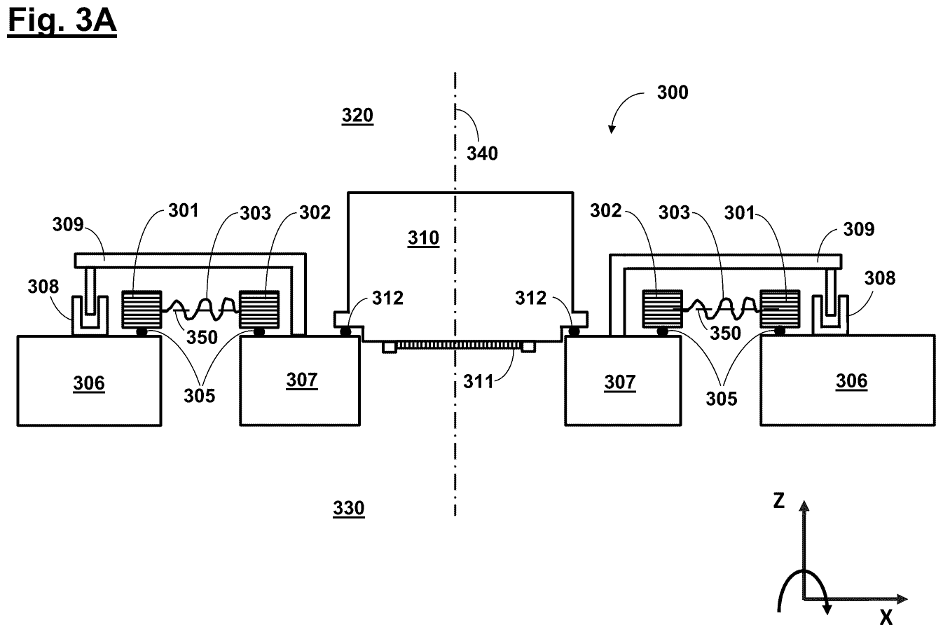

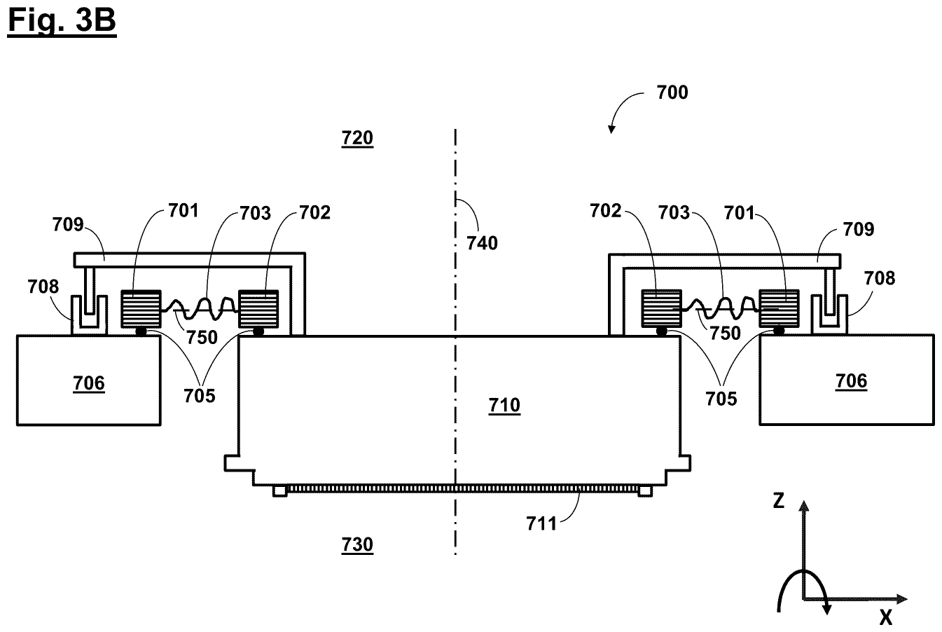

In the exemplary use scenario that is in particular envisaged according to the invention, as described below with reference to FIGS. 3-6, the first component is a vacuum housing 106 (indicated merely schematically in part in FIG. 1) of a mask inspection apparatus, and the second component is a camera holder 107 (also merely indicated in FIG. 1) for an EUV camera of this mask inspection apparatus. In the exemplary use scenario, the vacuum seal component according to the invention is thus located between a vacuum chamber 130 and an outer region 120, exposed to the atmospheric pressure, of a mask inspection apparatus.

To this end, the material of the flexible wall portion 103 is a vacuum-suitable (in particular ultra-high-vacuum-suitable) material.

According to one embodiment, the material of the flexible wall portion 103 is a material suitable for operation in ultra-high vacuum or at a partial pressure less than 10⁻⁷ pascals (“ultra-high vacuum” being defined as the region from 10⁻⁷ pascals to 10⁻¹² pascals). In some embodiments, the material of the flexible wall portion 103 may also be a material suitable for operation in high vacuum (“high vacuum” being defined as the region between 10⁻³ and 10⁻⁷ pascals).

This material may in particular be a metallic material (e.g. stainless steel or aluminium (Al)), wherein, for the provision of the required flexibility as described below, a fold structure indicated in FIG. 1 is formed on the wall portion 103. With reference to FIG. 2, said wall portion 103 then has folds which are concentric in relation to the origin of the coordinate system shown therein or the central axis 140 running through said origin in the z-direction.

The shape, geometry and dimensions of the flexible wall portion 103 (in particular the shape and geometry of the “folds” and “fold structure”) may be optimized depending on the specific application scenario, such as dynamic circumstances, the mass to be supported (e.g. mass of the EUV camera), the ratio between the opening size (of the respective opening in the vacuum housing) and the size of the EUV camera itself. The flexible wall portion 103 preferably has a circular disc shape. In other embodiments, the flexible wall portion may also have an oval disc shape. The thickness of the flexible wall portion 103 is appropriately selected dependent on the material. The elasticity coefficient of the flexible wall portion 103 is selected such that the flexible wall portion 103 shows no plastic deformation (which would lead to an undesired stress on the surrounding structure). In some implementations, appropriate values of the modulus of elasticity of the flexible wall portion 103 are e.g. in the range from 68 kN/mm² (=value of the E-modulus for aluminium, Al) and 210 kN/mm² (=value of the E-modulus for steel).

However, the invention is not restricted to such a fold structure or bellows structure of the flexible wall portion 103. In further embodiments, the flexible wall portion 103 may also have an annular-disc-like or perforated-disc-like geometry without such folds, the required flexibility then being able to be provided by the material of the wall portion 103 itself and/or by a sufficiently low thickness thereof. In addition to metallic materials, the use of vacuum-suitable rubber materials (with defined outgassing behaviour) is also possible. The outgassing values of typical rubber materials, which may be appropriate depending on the specific system requirements, may be (if given in mbar*L/(cm²*s), respectively) in the range between 6*10⁻⁸ and 4*10⁻⁷ for H₂O (escaping from the rubber material), between 1*10⁻¹¹ and 1*10⁻¹⁰ for outgassing of light hydrocarbons (LHC) and between 8*10⁻¹³ and 4*10⁻¹² for outgassing of heavy hydrocarbons (HHC).

What is common to the embodiment described on the basis of FIGS. 1-2 and also the embodiment described below is a geometric arrangement which is particularly advantageous from aspects of installation space: accordingly, as can be seen both from FIG. 1 and from FIG. 2, a plane 150, denoted by “150” in FIG. 1 (and corresponding to the xy-plane in FIG. 2), of the wall portion 103 runs substantially perpendicularly (in particular at an angle in the range from 80° to 100°) with respect to the central axis, denoted by “140”, of the arrangement. This achieves a significant saving on installation space in an axial direction in relation to said central axis 140, and at the same time a flexible adaptation which is required for a desired position manipulation or adjustability of the components mounted on the flange elements 101, 102 relative to one another (that is to say in particular of the vacuum housing 106 and the camera holder 107 in the use scenario of the mask inspection apparatus) is enabled while ensuring the vacuum conditions.

In embodiments, the angle between a plane 150 defined by the wall portion 103 and the central axis 140 may have a value in the range from 0° to 180°, in particular in the range from 45° to 135°, more particularly in the range from 80° to 100°, more particularly in the range from 85° to 95°, more particularly 90°. These angle specifications preferably refer to a configuration in which a tilting, described below and realizable according to the invention, has not yet been carried out and the wall portion 103 is thus in a position as shown in FIG. 1. The plane 150 defined by the wall portion 150 can in particular be the so-called neutral axis (or neutral fiber) of the wall portion 150.

The mentioned position manipulation or adjustability may in this case be effected in particular in up to five degrees of freedom, namely the translational degrees of freedom in the x-, y- and z-direction and the rotational degrees of freedom Rₓ (corresponding to a tilting or rotation about the x-axis) and R_{y} (corresponding to a tilting or rotation about the y-axis). In embodiments, this tilting may be realizable in particular at least up to an angle of 5°, in particular up to an angle of 10° with respect to the central axis.

The invention is not restricted to a rotationally symmetrical design of the flexible wall portion 103 and of the flange elements 101, 102 as shown in FIG. 2, with an elliptical geometry, for example, also being possible.

FIG. 3A shows a schematic illustration for explaining the mechanical attachment of the assembly from FIG. 1 to an EUV camera of a mask inspection apparatus with realization of an adjustment mechanism. Components analogous or substantially functionally identical in comparison with FIG. 1 are denoted here by reference numerals increased by “200”. Here, an EUV camera of this mask inspection apparatus is denoted by “310”, and the vacuum seal component according to the invention is located between a vacuum chamber 330 and an outer region 320, exposed to the atmospheric pressure, of the mask inspection apparatus.

According to FIG. 3A, a plurality of actuator units 308 are arranged between the EUV camera 310 and the vacuum housing 306. An adjustment mechanism is denoted by “309”. The adjustment mechanism 309 can be a rigid piece of material that has a first portion connected to, and movable by, the actuator 308 and a second portion connected to the camera holder 307, such that when the actuator 308 moves the first portion of the adjustment mechanism 309, the second portion of the adjustment mechanism 309 is moved accordingly, which in turn moves the camera holder 307.

In the example shown in FIG. 3A, the EUV camera 310 and the vacuum housing 306 are held at a distance from one another by four actuator units 308, wherein the two actuator units 308 that are visible in FIG. 3A are spaced apart from one another in the X-direction, and wherein the two actuator units 308 that are not visible in FIG. 3A are spaced apart from one another in the Y-direction. The actuator units 308 can be adjusted in length independently of one another, as a result of which the distance between the EUV camera 310 and the vacuum housing 306 can be changed. The actuator units 308 are arranged radially outside of a vacuum seal component which is described below and has a flexible wall portion 303, such that the actuator units 308 are exposed to atmospheric pressure.

Suitable control of the actuator units 308 makes it possible to adjust the position of the EUV camera 310 relative to the vacuum housing 306. The EUV camera 310 can be tilted about the Y-axis by means of one of the two actuator units 308 that are visible in FIG. 3A being lengthened and the other being correspondingly shortened. The EUV camera 310 can be tilted about the X-axis by means of one of the two actuator units 308 that are not visible in FIG. 3A being lengthened and the other being correspondingly shortened. The EUV camera 310 can be displaced in the z-direction by means of all four actuator units 308 being jointly lengthened or shortened. The actuator units 308 are controlled by a control unit (not shown in FIG. 3A). The actuator units 308 can comprise, e.g., voice-coil actuators (comprising magnet-coil-pairs), screw actuators, lever arm actuators, hydraulic actuators or pneumatic actuators. The structure of the control unit and its operation to control the actuator units 308 depend on the specific design of the actuator units 308.

The force acting between the EUV camera 310 and the vacuum housing 306 comprises the weight force of the EUV camera 310 and the force resulting from the pressure difference between the vacuum pressure in the interior of the vacuum chamber 330 and atmospheric pressure. The force resulting from the pressure difference outweighs the weight force considerably, such that overall a force which corresponds to a weight force of several tonnes is produced. The total force is transmitted by way of the actuator units 308. If the position of the EUV camera 310 relative to the vacuum housing 306 is intended to be changed, the actuator units 308 must overcome this force.

According to FIG. 3A, the vacuum seal component having a flexible wall portion 303 is arranged between the vacuum housing 306 and a camera holder 307 of the EUV camera 310. This arrangement is effected geometrically radially outside of a central axis, denoted by “340”, of the EUV camera 310 or of the camera holder 307 such that a plane defined by the wall portion 303 runs orthogonally with respect to this central axis 340.

FIG. 3B shows a schematic illustration for explaining the mechanical attachment of the assembly from FIG. 1 to an EUV camera of a mask inspection apparatus according to a further embodiment. Components analogous or substantially functionally identical in comparison with FIG. 3A are denoted, in FIG. 3B, by reference numerals increased by “400”. The embodiment of FIG. 3B differs from FIG. 3A in so far as the vacuum seal component having a flexible wall portion 703 is arranged between the vacuum housing 706 and the EUV camera 710. The adjustment mechanism 709 can be a rigid piece of material that has a first portion connected to, and movable by, the actuator 708 and a second portion connected to the camera 710, such that when the actuator 708 moves the first portion of the adjustment mechanism 709, the second portion of the adjustment mechanism 709 is moved accordingly, which in turn moves the camera 710.

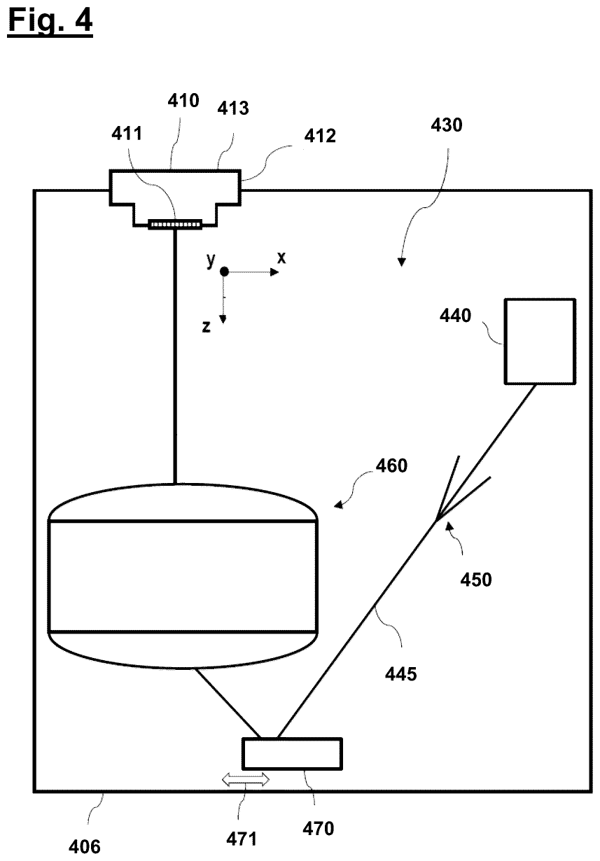

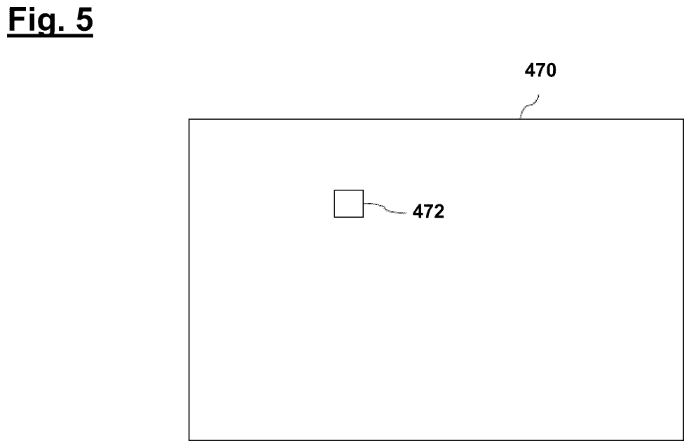

FIGS. 4-6 show schematic illustrations for explaining a possible basic construction of a mask inspection apparatus. Accordingly, a mask inspection apparatus in particular comprises an illumination system 450 and a projection lens 460, wherein an EUV beam path 445 originating from an EUV radiation source 440 is routed via the illumination system 450 onto an EUV mask 470. The illumination system 450 is used to shape the EUV radiation to form a beam used to illuminate, with uniform brightness, an examination field on the surface of the EUV mask 470. The examination field 472, which is small in comparison with the area of the EUV mask 470, is illustrated in FIG. 5 in an illustration that is not true to scale. The illuminated region 472 may, for example, have dimensions of 0.5 mm*0.8 mm. The edge lengths of the EUV mask 470 may, for example, be between 100 mm and 200 mm. A field stop used to delimit the illuminated region to the examination field 472 on the surface of the EUV mask 470 is arranged in the illumination system 450. Using a positioning mechanism 471, it is possible to move the EUV mask 470 in the horizontal plane in order to bring different examination fields 472 into the region of the EUV beam path. The EUV mask 470 may, for example, have an aspect ratio of between 1:1 and 1:3, preferably between 1:1 and 1:2, particularly preferably of 1:1 or 1:2; it can be of substantially rectangular design.

The EUV beam path 445 reflected at the EUV mask 470 continues through the projection lens 460 to an EUV camera 410, which is equipped with an image sensor 411, which can be, e.g., a charge coupled device (CCD) or complementary metal oxide semiconductor (CMOS) sensor, that has an array of independently addressable sensing elements. The projection lens 460 is used to image the examination field 472 of the EUV mask 470 onto the image sensor 411 of the EUV camera 410. The imaging beam path 445 is incident on the image sensor 411 in the z-direction. The EUV radiation source 440, the illumination system 450, the EUV mask 470, the projection lens 460 and the image sensor 411 of the EUV camera 410 are arranged in a vacuum chamber 430 surrounded by a vacuum housing 406. During operation of the mask inspection apparatus, a high vacuum is present in the vacuum chamber 430. The EUV camera 410 comprises a camera housing 412, which carries the image sensor 411. A rear-side part 413 of the camera housing 412 projects out of the vacuum housing 406, while the image sensor 411 is exposed to the vacuum in the vacuum housing 406.

The EUV radiation source 440 is a plasma radiation source for generating EUV radiation at a wavelength of approximately 13.5 nm.

The mirrors in the illumination system 450 and the mirrors in the projection lens 460 are designed as EUV mirrors which have a particularly high reflectivity for EUV radiation. The optical area of the EUV mirrors can be formed by a highly reflective coating. This may be a multilayer coating, in particular a multilayer coating having alternating layers of molybdenum and silicon. Using such a coating, it is possible to reflect approximately 70% of the incident EUV radiation.

The projection lens 460 has a magnification factor of more than 100. In order to be able to record the entirety of the generated image of the examination field 472 of the EUV mask 470, the area of the image sensor 411 is greater than the area of the examination field 472 in accordance with the magnification factor. The image sensor 411 may, for example, have dimensions of the order of magnitude of 100 mm to 200 mm.

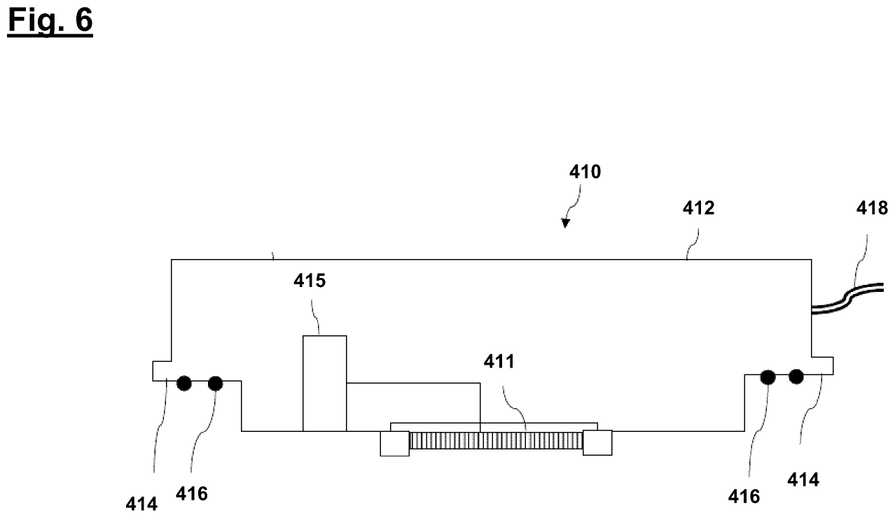

According to FIG. 6, the image sensor 411 and an electronics unit 415 are arranged on the camera housing 412 of the EUV camera 410. By use of the electronics unit 415, the image sensor 411 is controlled, and the EUV image data obtained by the image sensor 411 are processed and output as sensor data. Via supply lines 418, the EUV camera 410 is supplied with electrical energy, the sensor data are transferred and a cooling device (not illustrated) is operated, by means of which components of the EUV camera 410 are cooled to a desired temperature.

A vacuum flange 414 is formed on the camera housing 412, and extends without interruption over the periphery of the camera housing 412. A seal is denoted by “416”. A connection between the EUV camera 410 and the vacuum housing 406 is established via the vacuum flange 414. In the mounted state, the rear side 413 of the camera housing 412 together with the vacuum housing 406 forms a portion of the wall of the vacuum chamber 430.

Although the invention has also been described on the basis of special embodiments, numerous variations and alternative embodiments, e.g. by combining and/or exchanging features of individual embodiments, can be discerned by those skilled in the art. For example, the projection lens 460 can include one or more lenses, reflectors, filters, and/or stops. Accordingly, it is understood by those skilled in the art that such variations and alternative embodiments are also comprised by the present invention, and the scope of the invention is limited only within the meaning of the appended claims and their equivalents.

What is claimed is:

1. A mask inspection apparatus, comprising a vacuum housing, an EUV camera mounted on the vacuum housing, and a projection lens, arranged in a vacuum chamber of the vacuum housing, for imaging at least one section of an EUV mask onto an image sensor of the EUV camera,
wherein a vacuum seal component having a flexible wall portion is arranged between the vacuum housing and the EUV camera or a camera holder of this EUV camera, and
wherein this flexible wall portion is arranged radially outside of a central axis of the EUV camera or of the camera holder.

2. The mask inspection apparatus of claim 1, wherein an angle between a plane defined by the wall portion and the central axis has a value in the range from 0° to 180°.

3. The mask inspection apparatus of claim 1, wherein an angle between a plane defined by the wall portion and the central axis has a value in the range from 45° to 135°.

4. The mask inspection apparatus of claim 1, wherein an angle between a plane defined by the wall portion and the central axis has a value in the range from 80° to 100°.

5. The mask inspection apparatus of claim 1, wherein an angle between a plane defined by the wall portion and the central axis has a value in the range from 85° to 95°.

6. The mask inspection apparatus of claim 1, wherein a plane defined by the wall portion runs orthogonally with respect to the central axis.

7. The mask inspection apparatus of claim 1, wherein the wall portion has a fold structure running around the central axis.

8. The mask inspection apparatus of claim 1, wherein the wall portion is produced from a metallic material, in particular stainless steel.

9. The mask inspection apparatus of claim 1, wherein the wall portion is produced from a vacuum-suitable flexible material, in particular a vacuum-suitable rubber material.

10. The mask inspection apparatus of claim 1, comprising an adjustment mechanism by way of which the position of the EUV camera is adjustable relative to the vacuum housing.

11. The mask inspection apparatus of claim 10, wherein this adjustability comprises a translational displacement in the direction of the central axis, in particular with an adjustment travel at least in the range from 0.1 mm to 2 mm.

12. The mask inspection apparatus of claim 10, wherein this adjustability comprises a tilting about at least one axis which is orthogonal to the central axis, in particular about two axes which are orthogonal to one another and to the central axis.

13. The mask inspection apparatus of claim 12, wherein this tilting is realizable at least up to an angle of 5°, in particular up to an angle of 10° with respect to the central axis.

14. A vacuum seal component, in particular for use in a mask inspection apparatus of claim 1, comprising
a flexible wall portion which extends around a central axis of the vacuum seal component, there being fastened to the flexible wall portion radially at the outside in relation to the central axis a first flange element for fastening to a first component and radially at the inside in relation to the central axis a second flange element for fastening to a second component.

15. The vacuum seal component of claim 14, wherein an angle between a plane defined by the wall portion and the central axis has a value in the range from 0° to 180°.

16. The vacuum seal component of claim 14, wherein an angle between a plane defined by the wall portion and the central axis has a value in the range from 45° to 135°.

17. The vacuum seal component of claim 14, wherein an angle between a plane defined by the wall portion and the central axis has a value in the range from 80° to 100°.

18. The vacuum seal component of claim 14, wherein an angle between a plane defined by the wall portion and the central axis has a value in the range from 85° to 95°.

19. The vacuum seal component of claim 14, wherein a plane defined by the wall portion runs orthogonally with respect to the central axis.

20. The vacuum seal component of claim 14, wherein the wall portion has a fold structure running around the central axis.

21. The vacuum seal component of claim 14, wherein the wall portion is produced from a metallic material, in particular stainless steel.

22. The vacuum seal component of claim 14, wherein the wall portion is produced from a vacuum-suitable rubber material.

23. A method for adjusting a mask inspection apparatus, wherein the mask inspection apparatus comprises a vacuum housing, an EUV camera mounted on the vacuum housing, and a projection lens, arranged in a vacuum chamber of the vacuum housing, for imaging at least one section of an EUV mask onto an image sensor of the EUV camera,
wherein the mask inspection apparatus is designed according to claim 1; and
wherein the position of the EUV camera is adjusted relative to the vacuum housing, in order to adjust the EUV camera relative to an imaging beam path of the projection lens.
